(19) United States
(12) Patent Application Publication
(10) Pub. No.: US 2026/0122788 A1
(43) Pub. Date: Apr. 30, 2026

(54) HYBRID MOLD, METHOD FOR MANUFACTURING HYBRID MOLD, WIRING STRUCTURE, AND METHOD FOR MANUFACTURING WIRING STRUCTURE

(71) Applicant: Panasonic Intellectual Property Management Co., Ltd., Osaka (JP)

(72) Inventors: AYA KUROKAWA, Tottori (JP); DAISUKE SAKURAI, Osaka (JP); KIYOKAZU ITOI, Osaka (JP); TAKAHIRO KUMAKAWA, Kyoto (JP)

(21) Appl. No.: 19/366,590

(22) Filed: Oct. 23, 2025

(30) Foreign Application Priority Data
Oct. 30, 2024 (JP) 2024-190410

(51) Int. Cl. H05K 3/10; H05K 1/11; H05K 3/12

(52) U.S. Cl. CPC H05K 3/101; H05K 1/115; H05K 3/1283; H05K 2203/0554; H05K 2203/0582; H05K 2203/0789

(57) ABSTRACT

A hybrid mold that is used for forming a wiring structure including wiring and vias connecting pieces of the wiring in different layers to each other, the hybrid mold includes a body made of an optically transparent material, a masking pattern made of an opaque material and disposed on a first surface of the body and a pillar structure including a plurality of pillars made of the optically transparent material and protruding from a second surface of the body, the second surface being opposite to the first surface. The masking pattern has shape and placement corresponding to shape and placement of the wiring when viewed from a direction orthogonal to the first surface, and the plurality of pillars each has shape and placement corresponding to shape and placement of the vias when viewed from the direction orthogonal to the first surface.

### BACKGROUND

### 1. Technical Field

The present disclosure relates to a hybrid mold, a method for manufacturing a hybrid mold, a wiring structure, and a method for manufacturing a wiring structure.

### 2. Description of the Related Art

In recent years, electronic components and devices have progressed in miniaturization, high functionality, and multi-functionalization. To respond to these needs, semiconductor chips mounted on electronic components and the like are desired to achieve densification of elements and narrower pitches of wirings.

For example, an interposer, which is a wiring substrate inserted between a semiconductor chip and a mounting substrate, functions to effectively connect semiconductor devices and modules having different shapes and pitches. Thus, using an interposer in an electronic component or the like enables forming a circuit with high density. Examples of the interposer include a glass interposer and an organic interposer depending on a material of a base. When a via is formed in the interposer, a via hole is formed in the base by etching, photolithography, or the like, and then metal plating or the like is applied to the inside of the via hole to form the via, for example. When wiring is formed in the interposer, a mask pattern is formed on a front surface and/or a back surface of the interposer. Metal plating or the like is applied to the inside of the mask pattern, and then the mask pattern is removed to form the wiring. The via in the interposer is used to connect pieces of wiring in different layers to each other or connect the wiring and a land electrode provided on the front surface and/or the back surface of the interposer.

Meanwhile, an imprint method has attracted attention as a method for forming wiring in recent years instead of etching or photolithography. The imprint method is configured to form a mask pattern or a via hole using a hybrid mold provided with a fine pattern by transferring the fine pattern to an insulating resist made of an insulating material and curing the insulating resist. In the method, the cured insulating resist is not removed and constitutes a part of the base of the interposer. The hybrid mold is a photomask-integrated imprint mold that has both imprint and photomask functions.

Examples of the imprint method include a thermal imprint method and a UV imprint method. The thermal imprint method is performed as follows: applying an insulating resist to a base; pressing and pressuring a hybrid mold against a surface of the base while heat is applied to increase fluidity of the insulating resist to form a mask pattern or a via hole in the insulating resist; and then releasing the hybrid mold. UV imprint is a method performed as follows: applying a UV-curable insulating resist to a base; pressing a hybrid mold against a surface of the base coated with the insulating resist; and then irradiating the insulating resist with UV light to cure the insulating resist, thereby forming a mask pattern or a via hole. These imprint methods enable forming a fine pattern with high accuracy.

In recent years, development of a multistage hybrid mold for imprint has been advanced, and various methods for forming the multistage hybrid mold have also been proposed (e.g., see Patent Literature (PTL) 1). This multistage hybrid mold is used in an imprint method that enables not only collectively forming a via and a wiring pattern, but also efficiently forming a three-dimensional multilayer wiring structure by stacking a plurality of conductive layers.

PTL 1: Unexamined Japanese Patent Publication No. 2012-23242

### SUMMARY

To achieve the above object, a hybrid mold according to an aspect of the present disclosure that is used for forming a wiring structure including wiring and vias connecting pieces of the wiring in different layers to each other, the hybrid mold including: a body made of an optically transparent material; a masking pattern made of an opaque material and disposed on a first surface of the body; and a pillar structure including a plurality of pillars made of the optically transparent material and protruding from a second surface of the body, the second surface being opposite to the first surface, in which the masking pattern has shape and placement corresponding to shape and placement of the wiring when viewed from a direction orthogonal to the first surface, and the plurality of pillars each has shape and placement corresponding to shape and placement of the vias when viewed from the direction orthogonal to the first surface.

A method for manufacturing a hybrid mold according to another aspect of the present disclosure is performed to manufacture the hybrid mold used for forming a wiring structure including wiring and vias connecting pieces of the wiring in different layers to each other, the method including steps of: forming a first hard mask layer on a back surface of a base made of an optically transparent material; forming a first resist film on the first hard mask layer and processing the first resist film to form a first resist pattern; etching the first hard mask layer using the first resist pattern as a mask to form a first hard mask pattern; etching the base using the first hard mask pattern as a mask to form a pillar structure including a plurality of pillars; removing at least the first resist pattern; and forming a masking pattern made of an opaque material on a surface of the base.

A wiring structure according to yet another aspect of the present disclosure includes: a first base; an insulating structure in which a first insulating layer and a second insulating layer are stacked; and wiring and via disposed in the insulating structure, in which the second insulating layer is disposed on a surface of the first base, the first insulating layer is disposed on a surface of the second insulating layer, the wiring has a side surface in contact with the first insulating layer, the via has a side surface in contact with at least the second insulating layer, the first insulating layer is a cured product of a photosensitive material, and the second insulating layer is a cured product of a non-photosensitive material.

A method for manufacturing a wiring structure according to yet another aspect of the present disclosure is performed to manufacture the wiring structure using the hybrid mold, the method including steps of: applying a non-photoresist to a surface of a first base and then heating the non-photoresist at a first temperature; applying a photoresist to a surface of the non-photoresist after the heating; heating the first base at a second temperature to reduce fluidity of the non-photoresist and the photoresist after the photoresist is applied; pressurizing the hybrid mold toward the first base while the fluidity of the non-photoresist is reduced and a tip of each of the plurality of pillars is in contact with the photoresist; forming an uncured part in the photoresist by emitting UV light from the first surface of the hybrid mold; releasing the hybrid mold from the non-photoresist and the photoresist; removing the photoresist uncured by cleaning; heating the first base at a third temperature after performing the step of releasing the hybrid mold or after performing the step of removing the photoresist uncured to fully cure at least the non-photoresist; and plating a recess formed in a stacked body of a cured product of the photoresist and a cured product of the non-photoresist to collectively form the vias and the wiring.

### BRIEF DESCRIPTION OF THE DRAWINGS

FIG. 1A is a schematic sectional view of a hybrid mold according to a first exemplary embodiment;

FIG. 1B is a schematic view of the hybrid mold according to the first exemplary embodiment as viewed from a direction orthogonal to a first surface;

FIG. 1C is a perspective view of the hybrid mold according to the first exemplary embodiment;

FIG. 2A is a schematic view illustrating a step of manufacturing the hybrid mold according to the first exemplary embodiment;

FIG. 2B is a schematic view illustrating a manufacturing step subsequent to that illustrated in FIG. 2A;

FIG. 3A is a schematic view illustrating another manufacturing step of the hybrid mold according to the first exemplary embodiment;

FIG. 3B is a schematic view illustrating a manufacturing step subsequent to that illustrated in FIG. 3A;

FIG. 4 is a schematic view illustrating a manufacturing step of a wiring structure according to the first exemplary embodiment;

FIG. 5 is a perspective view of the wiring structure according to the first exemplary embodiment;

FIG. 6A is a schematic sectional view of a hybrid mold according to a second exemplary embodiment;

FIG. 6B is a schematic view of the hybrid mold according to the second exemplary embodiment as viewed from a direction orthogonal to a first surface;

FIG. 6C is a perspective view of the hybrid mold according to the second exemplary embodiment;

FIG. 7 is a schematic view illustrating a manufacturing step of a wiring structure according to the second exemplary embodiment;

FIG. 8A is a schematic sectional view of a hybrid mold according to a third exemplary embodiment;

FIG. 8B is a schematic view of the hybrid mold according to the third exemplary embodiment as viewed from a direction orthogonal to a first surface;

FIG. 8C is a perspective view of the hybrid mold according to the third exemplary embodiment;

FIG. 9A is a schematic view illustrating a step of manufacturing the hybrid mold according to the third exemplary embodiment;

FIG. 9B is a schematic view illustrating a manufacturing step subsequent to that illustrated in FIG. 9A;

FIG. 10 is a schematic view illustrating a manufacturing step of a wiring structure according to the third exemplary embodiment; and

FIG. 11 is a schematic view illustrating a manufacturing step of another hybrid mold.

### DETAILED DESCRIPTIONS

The method disclosed in PTL 1 has difficulty in aligning and processing a first step and a second step formed on a hybrid mold. Thus, alignment accuracy of a fine pattern of 1 μm or less is less likely to be ensured, and a desired pattern may not be obtained. The method disclosed in PTL 1 increases manufacturing cost of the hybrid mold because multiple steps are formed on a base.

When imprinting is performed using a multistage hybrid mold, a total aspect ratio of steps, that is, a ratio between a width and a height of each step is higher than when imprinting is performed using a hybrid mold having one step. When the multistage hybrid mold is used, a cured insulating material adheres to the entire surface provided with the multiple steps of the hybrid mold immediately after the imprinting, and thus mold releasability of the hybrid mold is deteriorated.

The present disclosure has been made in view of such a point, and an object of the present disclosure is to provide a hybrid mold capable of easily manufacturing and processing a wiring structure, a method for manufacturing the hybrid mold, the wiring structure, and a method for manufacturing the wiring structure.

Exemplary embodiments of the present disclosure will be described below with reference to the drawings. The description below of a preferred exemplary embodiment is merely exemplary in nature, and is not intended to limit the present disclosure, its applications, or its use.

### First exemplary embodiment

### Structure of hybrid mold

Structure of a hybrid mold will be described below with reference to the drawings.

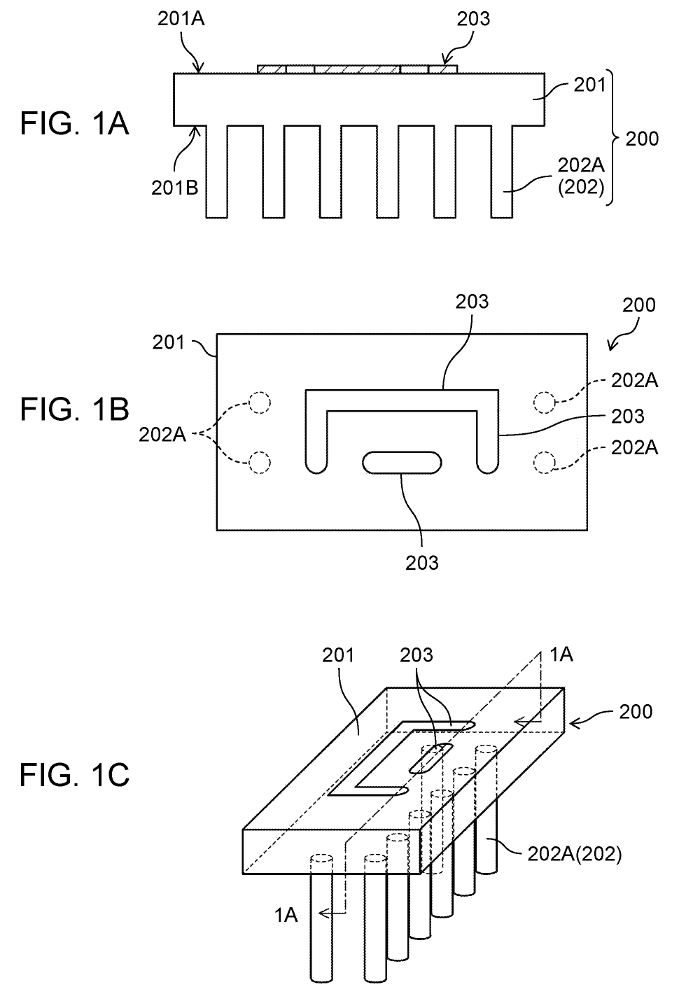

FIG. 1A is a schematic sectional view of a hybrid mold according to the present exemplary embodiment. FIG. 1B is a schematic view of the hybrid mold as viewed from a direction orthogonal to a first surface. FIG. 1C is a perspective view of the hybrid mold.

FIG. 1A corresponds to a section taken along line 1A-1A in FIG. 1C. Each drawing shown below has a sectional view corresponding to a section taken along line 1A-1A that is an imaginary line identical for each drawing.

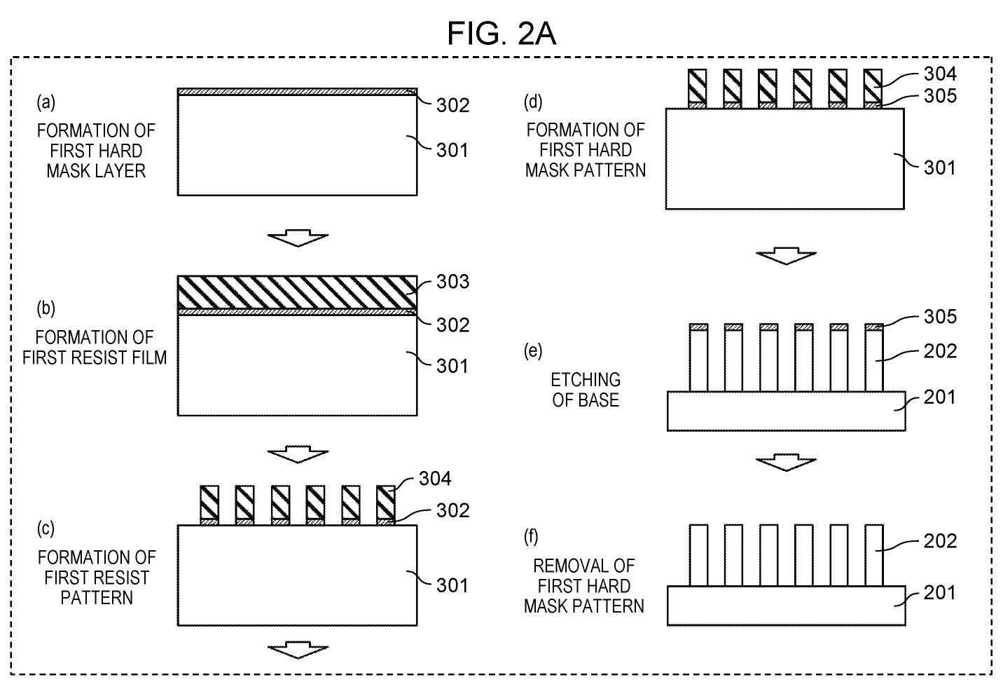

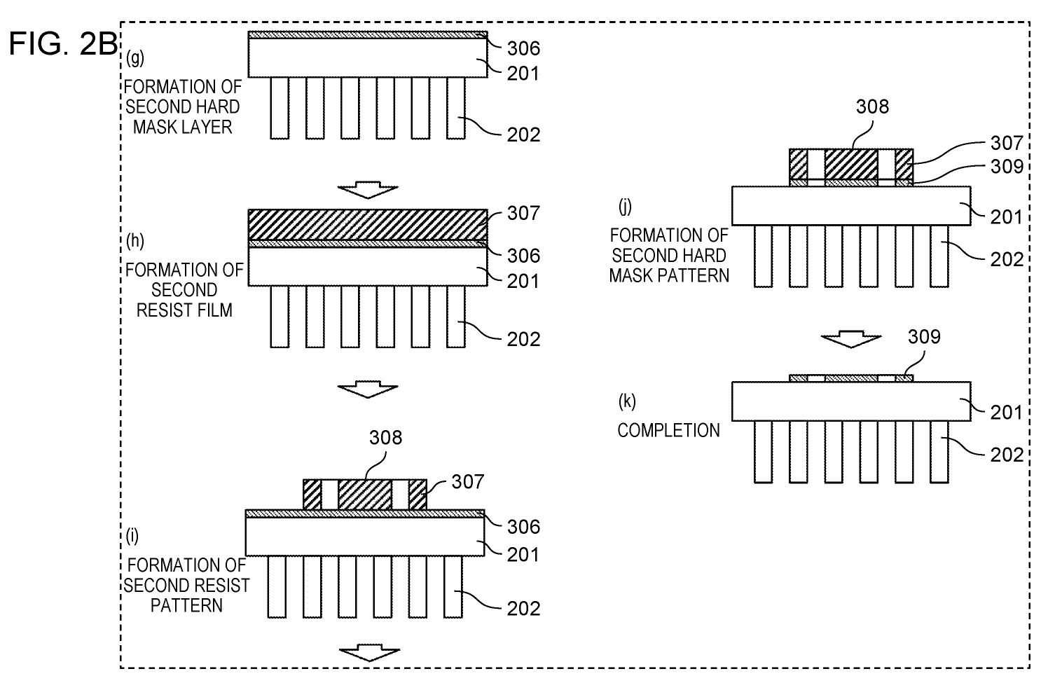

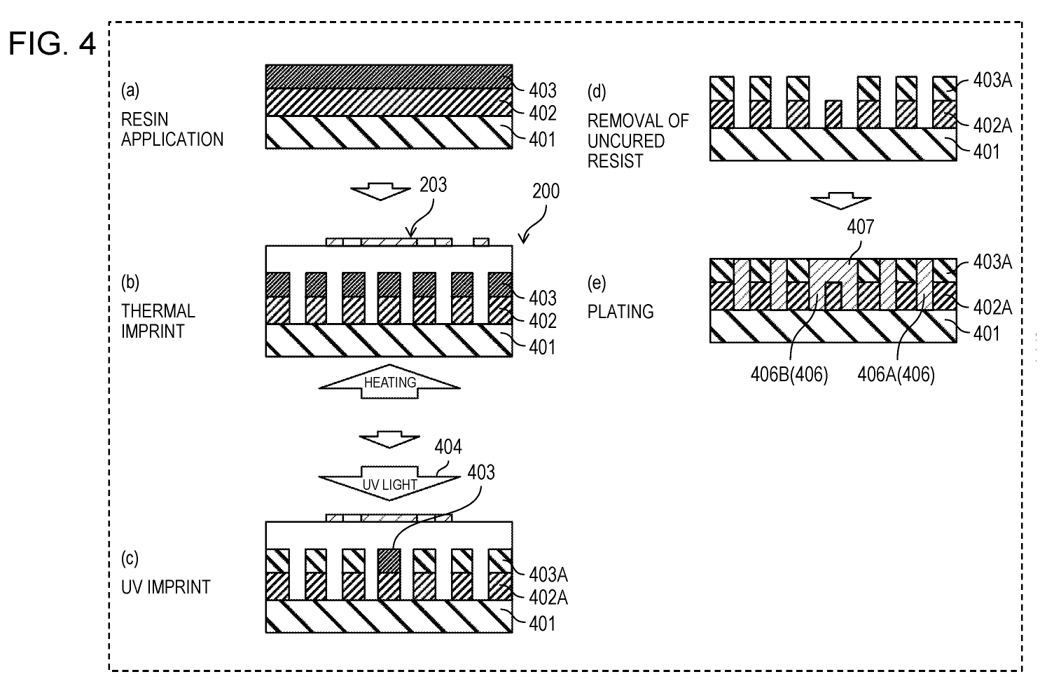

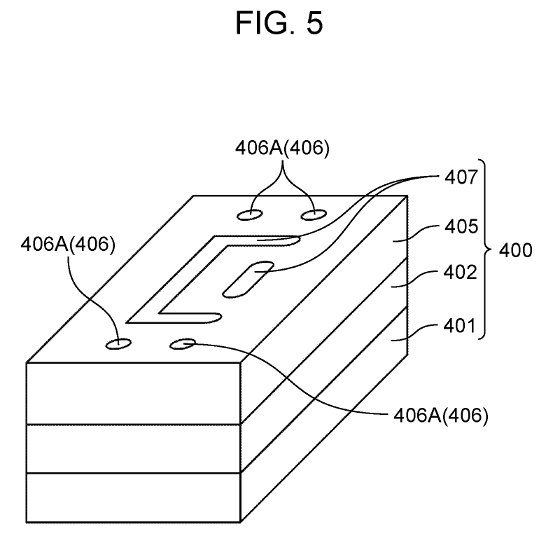

FIGS. 1A to 1C each illustrate hybrid mold 200 that includes body 201, pillar structure 202, and masking pattern 203. As described later, body 201 and pillar structure 202 are obtained by processing base 301 (see FIGS. 2A, 2B) made of an optically transparent material. That is, body 201 and pillar structure 202 are integrally formed. Hybrid mold 200 is a component used for manufacturing wiring structure 400 (see FIGS. 4, 5) described later, and is a so-called imprint mold.

Base 301, that is, a material of body 201 and pillar structure 202, is preferably an inorganic material such as quartz glass from the viewpoint of solidity and thermal stability, but may be a light transmissive resin. As described later, base 301 may be a material that allows UV light such as light having a wavelength of 380 μm or less to pass through the material. In the description below, base 301 is quartz glass.

Body 201 is a rectangular parallelepiped, and has first surface 201A provided with masking pattern 203. From second surface 201B opposite to first surface 201A, a plurality of pillars 202A protrudes at intervals from each other. Pillar structure 202 is a set of the plurality of pillars 202A. Pillar 202A in the present exemplary embodiment has a height of about several μm and a diameter of about 1 μm, but is not particularly limited to the height and the diameter, and each pillar can be appropriately changed in height and diameter. For example, pillar 202A may have a height of 10 μm, or a diameter of about several μm in the first decimal place to several μm. That is, pillars 202A on second surface 201B may be provided at a pitch of about 1 μm to several μm.

Each masking pattern 203 is made of an opaque material. The opaque material may be any material that shields the UV light described above. Available examples include chromium (Cr), aluminum (Al), silicon oxide (SiOx), and silicon nitride (SiNx). Chromium is preferably selected as the opaque material from the viewpoint of having a high light shielding property against the UV light.

Masking pattern 203 has shape and placement as viewed from a direction orthogonal to first surface 201A, the shape and placement corresponding to shape and placement of wiring 407 (see FIGS. 4, 5) in wiring structure 400. Pillar structure 202, that is, the plurality of pillars 202A, has shape and placement as viewed from the direction orthogonal to first surface 201A, the shape and placement corresponding to shape and placement of vias 406 in wiring structure 400.

### Method for manufacturing hybrid mold

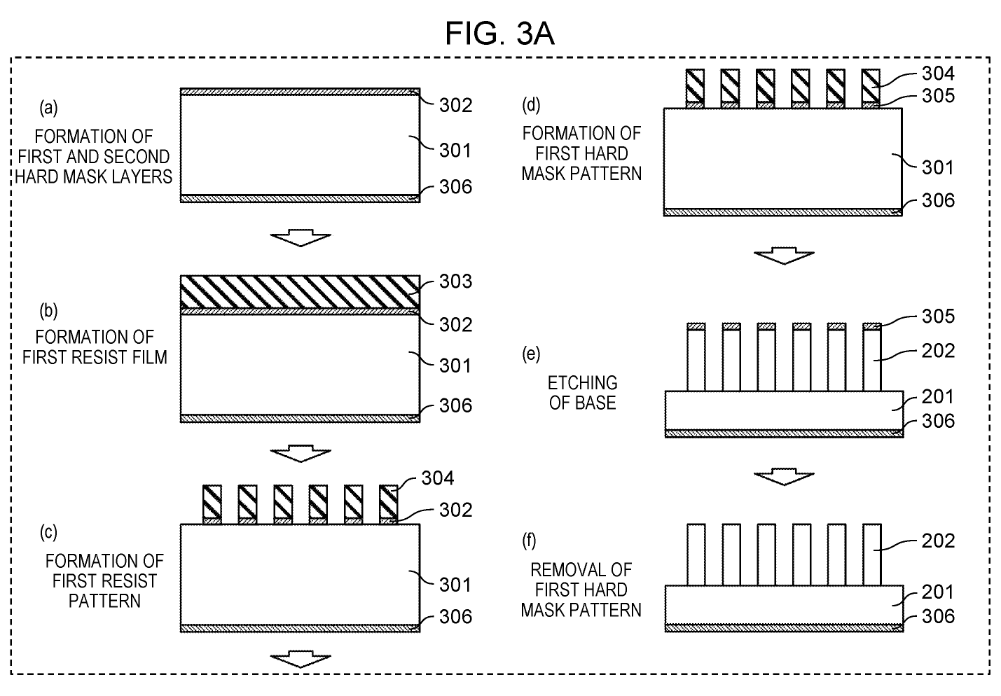

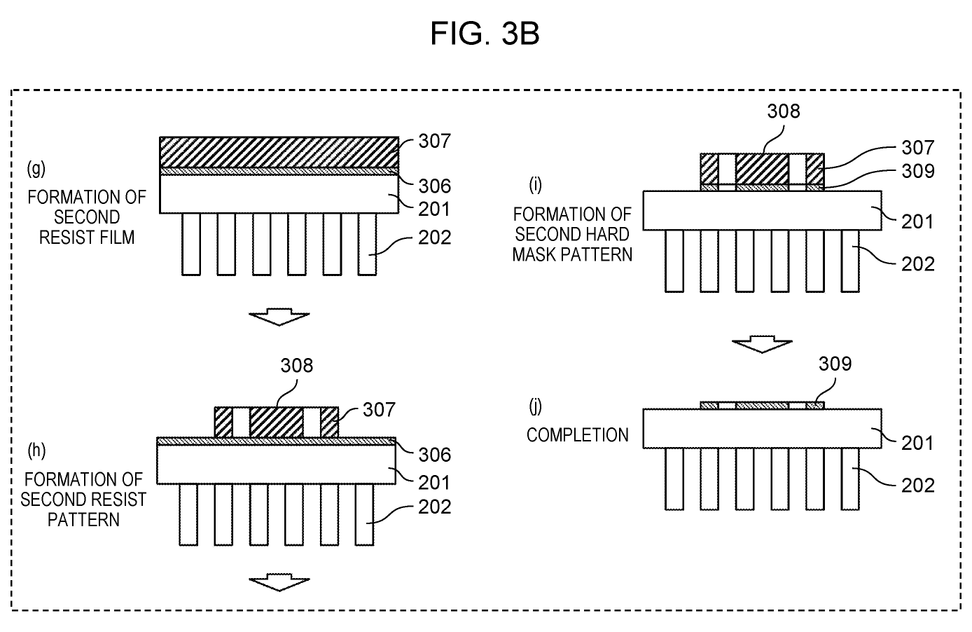

FIG. 2A is a schematic view illustrating a step of manufacturing a hybrid mold according to the first exemplary embodiment. FIG. 2B is a schematic view illustrating a manufacturing step subsequent to that illustrated in FIG. 2A. FIG. 3A is a schematic view illustrating another manufacturing step of the hybrid mold according to the first exemplary embodiment. FIG. 3B is a schematic view illustrating a manufacturing step subsequent to that illustrated in FIG. 3A.

### a: Formation of first hard mask layer

As illustrated in FIG. 2A, after base 301 is prepared, first hard mask layer 302 is formed on a back surface of base 301. The back surface of base 301 corresponds to second surface 201B of body 201. First hard mask layer 302 is formed by a method that is appropriately selected from a sputtering method, an electron beam vapor deposition method, a chemical vapor deposition (CVD) method, and the like.

First hard mask layer 302 is processed to obtain first hard mask pattern 305 that is used as an etching mask of base 301 described later. Thus, first hard mask layer 302 is made of a material selected from materials having not only high corrosion resistance to etching processing of base 301 being quartz glass but also a high etching selectivity to quartz glass of a predetermined level or more. For example, the material of first hard mask layer 302 is selected from chromium, aluminum, silicon oxide, silicon nitride, and the like. Among them, the material of first hard mask layer 302 is preferably chromium from the viewpoint of corrosion resistance and an etching selectivity to quartz glass.

### b: Formation of first resist film

Next, first resist film 303, which is a photoresist, is formed on first hard mask layer 302. First resist film 303 in the present exemplary embodiment is formed by a method that is a coating method for which a spin coating method or a die coating method is used.

### c: Formation of first resist pattern

Next, first resist film 303 is processed into first resist pattern 304 by a photolithography technique. That is, first resist pattern 304 is formed by performing exposure and development on first resist film 303 using an exposure mask (not illustrated). When a photolithography technique frequently used in semiconductor manufacturing technique is used for a photoresist as first resist film 303, first resist pattern 304 that is fine and has high dimensional accuracy can be formed.

### d: Formation of first hard mask pattern

Next, first hard mask layer 302 is processed into first hard mask pattern 305 by an etching technique using first resist pattern 304 as an etching mask. As the etching technique, dry etching using plasma, wet etching using an acidic or alkaline solution, or the like is used.

### e: Etching of base

Next, first resist pattern 304 is removed, and base 301 is anisotropically etched using remaining first hard mask pattern 305 as an etching mask to form pillar structure 202. In this step, base 301 is anisotropically etched so that pillar 202A has a height equal to a sum of a thickness of wiring 407 and a height of second via 406B described later. For example, base 301 is anisotropically etched so that pillar 202A has a height of about 5 μm to 6 μm.

Any one of dry etching and wet etching described above can be used as a method for the etching. However, the dry etching is preferably used when pillars 202A each have a diameter of 1 μm or less, or when an interval between pillars 202A adjacent to each other is less than or equal to a height of each pillar 202A. First resist pattern 304 may be removed after base 301 is anisotropically etched.

First resist pattern 304 is removed by a known resist strip process. Although examples of the resist strip process include a wet process and a dry process, any one of the processes may be used. The wet process is performed to remove first resist pattern 304 by being brought into contact with an alkaline solution, an amine-based solution, or an organic solvent-based stripping solution. The dry process is performed to ash first resist pattern 304 made of organic matter by exposing first resist pattern 304 to oxygen plasma or gas containing ozone. A residue of first resist pattern 304 may be removed with a cleaning liquid or the like after the ashing.

### f: Removal of first hard mask pattern

After pillar structure 202 is formed, first hard mask pattern 305 is removed.

Although examples of a process of removal of first hard mask pattern 305 also include a wet process using an acidic solution and a dry process, any one of the processes may be used. As the dry process, plasma etching using a mixed gas of a chlorine-based gas and a gas containing oxygen is used, for example.

### g: Formation of second hard mask layer

Next, second hard mask layer 306 is formed on a surface of base 301 as illustrated in FIG. 2B. The surface of base 301 corresponds to first surface 201A of body 201. Second hard mask layer 306 is formed by a method similar to that for first hard mask layer 302. Second hard mask layer 306 is processed to obtain masking pattern 203, and thus a material of second hard mask layer 306 is preferably chromium as described above.

### h: Formation of second resist film

Next, second resist film 307 is formed on second hard mask layer 306. Second resist film 307 is formed by a method similar to that for forming first resist film 303. For the reason described above, second resist film 307 is also a photoresist.

### i: Formation of second resist pattern

Next, second resist film 307 is processed into second resist pattern 308 by a photolithography technique. Second resist pattern 308 is formed by a method similar to that for forming first resist pattern 304. Body 201 is made of an optically transparent material, so that a shape of pillar structure 202 can be optically recognized as viewed from first surface 201A. Second resist film 307 is exposed to light while an exposure mask (not illustrated) for forming second resist pattern 308 is aligned with a corner or the like of pillar structure 202. Consequently, alignment accuracy between second resist pattern 308, eventually second hard mask pattern 309, and pillar structure 202 can be enhanced.

### j: Formation of second hard mask pattern

Next, second hard mask layer 306 is processed into second hard mask pattern 309 by an etching technique using second resist pattern 308 as an etching mask. Second hard mask pattern 309 is processed by a method similar to that for processing first hard mask pattern 305.

### k: Completion

Finally, second resist pattern 308 is removed to complete hybrid mold 200. Second resist pattern 308 is removed by a method similar to that for removing first resist pattern 304.

Applying mold release treatment to a surface of hybrid mold 200 after second resist pattern 308 is removed enables improving mold releasability of hybrid mold 200 during manufacturing of wiring structure 400 described later. The mold release treatment is applied to the surface of hybrid mold 200 by applying and fixing a release agent containing silicone or fluorine material such as a fluorine resin to the surface, for example.

A method for forming masking pattern 203 is not always limited to the method described above, that is, the method for processing second hard mask layer 306 formed on the surface of base 301 to obtain second hard mask pattern 309 as masking pattern 203.

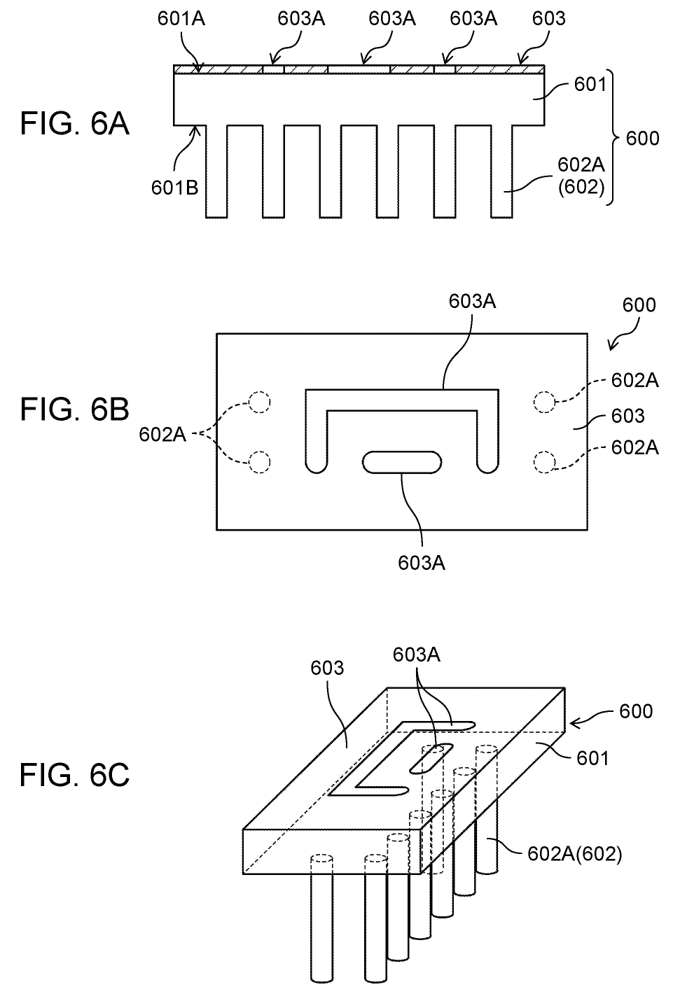

For example, masking pattern 203 may be obtained by selectively applying a reflective material to the surface of base 301. For masking pattern 203, a resist pattern having an opening pattern (not illustrated, and refer to FIGS. 6A to 6C for shape and placement of the opening pattern) is formed on the surface of base 301. The resist pattern is an inverted pattern of second hard mask pattern 309. As with first resist pattern 304 and second resist pattern 308, the resist pattern is formed using a known photolithography technique. After the resist pattern is formed, a reflective material is applied to the entire surface. After processing of fixing the applied reflective material to the surface of base 301 is performed, the resist pattern is removed to obtain masking pattern 203. The reflective material is acquired by dispersing a substance, which reflects UV light, in a solvent having a predetermined viscosity, for example. Although the reflective material is preferably left only inside the opening pattern, the reflective material may remain on an upper surface of the resist pattern because the reflective material is removed together when the resist pattern is removed.

A resist may be applied to the surface of base 301, and an opening pattern may be formed on the resist using an imprint mold having a structure similar to that of hybrid mold 200 illustrated in FIGS. 1A to 1C. For this formation, the imprint mold is pressed and pressurized against the resist while fluidity of the resist is reduced, as described later. When the imprint mold is released from the resist, the opening pattern is obtained.

### Configuration and manufacturing method of wiring structure

FIG. 4 is a schematic view illustrating a manufacturing step of a wiring structure according to the first exemplary embodiment. FIG. 5 is a perspective view of the wiring structure according to the first exemplary embodiment.

Hereinafter, a method for manufacturing wiring structure 400 using hybrid mold 200 illustrated in FIGS. 1A to 1C will be described with reference to FIG. 4.

### a: Resin application

First, non-photoresist 402 is applied to a surface of first base 401 made of an insulating material. After the application of non-photoresist 402, first base 401 is heated to pre-bake non-photoresist 402. Non-photoresist 402 is an insulating resist such as polyimide, and is cured by being heated to a predetermined temperature or higher.

When non-photoresist 402 is applied, the spin coating method or the die coating method described above is preferably used. Consequently, non-photoresist 402 can be improved in film thickness controllability and film thickness uniformity.

Non-photoresist 402 has a final film thickness that varies in accordance with the amount of volatilization of a solvent after prebaking. Thus, non-photoresist 402 is applied to have a target film thickness after the prebaking. Non-photoresist 402 in the present exemplary embodiment has a target film thickness of about 3 μm to 5 μm after the prebaking. However, the target film thickness may be appropriately changed depending on a design value of height of via 406 and a subsequent manufacturing process.

The prebaking is performed in the present exemplary embodiment at a temperature of about 90°C to 120°C, and for a time of about 1 minute to 5 minutes. However, these prebaking conditions are appropriately changed depending on a type of non-photoresist 402, conditions of thermal imprint described later, a model of an apparatus to be used, and the like.

After non-photoresist 402 is prebaked, photoresist 403 is applied to a surface of non-photoresist 402. Photoresist 403 in the present exemplary embodiment is a negative-type insulating resist. That is, a part irradiated with UV light is cured, but an unexposed part without being irradiated with the UV light becomes uncured without being cured. The uncured part can be easily removed using a developer. Photoresist 403 is applied by a method similar to that for applying non-photoresist 402. Photoresist 403 is applied to have a film thickness of about 2 μm to 3 μm after being applied. However, this film thickness may be appropriately changed depending on a design value of a height of wiring 407 and a subsequent manufacturing process.

### b: Thermal imprint

Next, first base 401 coated with non-photoresist 402 and photoresist 403 is heated to a predetermined temperature. Usually, a stage (not illustrated) on which first base 401 is placed is heated to the predetermined temperature.

Heating first base 401 lowers fluidity of each of non-photoresist 402 and photoresist 403, and thus facilitating molding using hybrid mold 200 during thermal imprint as described later. This step generally has a heating temperature of about 50°C to 200°C depending on a type of non-photoresist 402.

Hybrid mold 200 is pressed and pressurized toward first base 401 while first base 401 is heated at a predetermined temperature and a tip of pillar 202A is in contact with photoresist 403. Consequently, shapes of the plurality of pillars 202A in pillar structure 202 are transferred to an insulating structure including non-photoresist 402 and photoresist 403. Hybrid mold 200 is pressurized toward first base 401 at a pressure of about 1.5 MPa to 15 MPa. However, the pressure may be changed depending on the fluidity of non-photoresist 402.

After hybrid mold 200 is kept pressurized toward first base 401 for about 1 minute to 5 minutes, the stage is reduced in temperature to fix a shape of a transfer pattern. The mold release treatment described above is preferably applied to the surface of hybrid mold 200.

When wiring and/or a land electrode are/is formed in advance on the surface of first base 401, the wiring and the like are aligned with masking pattern 203 to align hybrid mold 200 with first base 401. Then, hybrid mold 200 is brought into contact with photoresist 403, and is further pressurized toward first base 401.

Photoresist 403 may be applied to the surface of non-photoresist 402 after first base 401 coated with non-photoresist 402 is heated to reduce the fluidity of non-photoresist 402. For the application of photoresist 403, hybrid mold 200 may be pressed and pressurized toward first base 401 without heating first base 401. As described above, when not only first base 401 is heated while being coated with non-photoresist 402 and photoresist 403, but also hybrid mold 200 is further pressed and pressurized toward first base 401, non-photoresist 402 and photoresist 403 are softened. Thus, moldability using hybrid mold 200 is improved.

### c: UV imprint

Next, UV light 404 is emitted from above photoresist 403. Photoresist 403 irradiated with UV light 404 is changed to insulating photo-cured product 403A. Meanwhile, photoresist 403 located immediately below masking pattern 203 of hybrid mold 200 remains uncured. UV light 404 may be emitted simultaneously with the temperature decrease of the stage described above.

After photoresist 403 without being shielded by masking pattern 203 is sufficiently cured, hybrid mold 200 is held by a vacuum suction nozzle (not illustrated) or the like. Then, the nozzle is pulled up to release hybrid mold 200 from the insulating structure.

After hybrid mold 200 is released, first base 401 provided with the insulating structure described above is heated again. Then, non-photoresist 402 is fully cured to change to insulating thermally-cured product 402A. Although temperature of full curing varies depending on a type and characteristics of resin constituting non-photoresist 402, the temperature is generally in a range of about 100°C to 200°C.

### d: Removal of uncured resist

Next, photoresist 403 is treated with a developer to remove an uncured part in photoresist 403. The uncured part corresponds to shape and placement of masking pattern 203 when viewed from above. Then, a remaining film of non-photoresist 402 remaining between the tip of pillar 202A before releasing and first base 401 is removed. The remaining film is removed using a method that may be wet cleaning using an acidic solution or an alkaline solution, or dry etching. Alternatively, organic washing using an organic solution may be used.

A step of fully curing non-photoresist 402 described above may be performed after a step of removing an uncured resist. Then, post-exposure baking may be performed after photoresist 403 is irradiated with UV light 404 and before processing with a developer. Performing the post-exposure baking suppresses change in shape of photo-cured product 403A due to development. When non-photoresist 402 is a polyimide-based resin material, a cured state changes in accordance with heating temperature. Thus, performing post-exposure baking before performing the full curing of non-photoresist 402 enables accelerating thermal curing of non-photoresist 402 to shorten full curing time.

When steps up to here are performed, a plurality of recesses can be formed in the insulating structure. These recesses each serve as a replica mold of a shape of via 406 and wiring 407 in wiring structure 400.

### e: Plating

Subsequently, metal plating is applied to first base 401 including the insulating structure, and the plurality of recesses formed in the insulating structure is filled with metal. These recesses include a through-hole passing through the insulating structure in its thickness direction, and the metal filled in the through-hole serves as first via 406A. Then, the metal filled in a recess formed after uncured photoresist 403 is removed serves as wiring 407. The metal filled in a via hole reaching first base 401 from a bottom surface of wiring 407 serves as second via 406B. That is, second via 406B is connected to wiring 407 in a thickness direction of wiring structure 400. First via 406A and second via 406B are collectively referred to as vias 406. That is, when the metal plating is performed, wiring 407 and vias 406 are simultaneously and collectively formed in the plurality of recesses formed in the insulating structure.

When the metal plating is performed, any one of electroless plating and electrolytic plating may be used. When the electrolytic plating is performed, the surface of first base 401 before non-photoresist 402 is applied is preferably provided with a seed layer made of a conductive material. The seed layer is a metal thin film made of any one of Cu, Ni, and Ti, for example.

First base 401 provided with the insulating structure is immersed in an electrolytic plating bath (not illustrated), and electricity is supplied between an electrode provided in the electrolytic plating bath and the seed layer. Then, metal grows on a surface of the seed layer to fill the recesses described above with the metal. A plating solution contains Cu or Au, for example, and fill plating of a bottom-up type is suitable. Consequently, even when the recesses each have a fine shape or a complicated shape, the plating solution is easily injected. For performing the plating without generating voids or the like in the recesses each having a fine shape, it is important to appropriately set a type and concentration of an additive contained in the plating solution, metal ion concentration in the plating solution, a circulation system and a flow rate of the plating solution, and the like. When the metal is filled by the electroless plating, the seed layer is unnecessary.

After a step of the metal plating is performed, the wiring structure illustrated in FIG. 5 is obtained. After the plating step is performed, wiring structure 400 provided with wiring 407 and vias 406 is preferably heated at a predetermined temperature. This heating treatment stabilizes the metal constituting wiring 407 and vias 406, and improves conductivity of wiring 407 and vias 406. The metal formed by the plating includes a part protruding from a surface of photoresist 403, the part being appropriately removed by chemical mechanical polishing (CMP) or the like as necessary.

When a land electrode or a wiring pattern is provided on any one or both of a surface on which wiring 407 is exposed and the surface of first base 401 in wiring structure 400 illustrated in FIG. 5, first via 406A is connected to the land electrode or the wiring pattern. That is, first via 406A connects pieces of wiring in different layers to each other. When one end of second via 406B is connected to a land electrode or a wiring pattern provided on the surface of first base 401, second via 406B also connects pieces of wiring in different layers to each other. In consideration of an interposer that is formed by stacking three or more wiring structures 400 illustrated in FIG. 5 in a thickness direction of each wiring structure, first via 406A may connect pieces of wiring in different layers to each other in the interposer in the following form. For example, a land electrode or a wiring pattern provided on a surface of another wiring structure 400 stacked on a lower side of wiring structure 400 provided with first via 406A and a land electrode or a wiring pattern provided on a surface of yet another wiring structure 400 stacked on an upper side thereof may be connected by first via 406A.

### Effects and the like

As described above, hybrid mold 200 according to the present exemplary embodiment is used to form wiring structure 400 including wiring 407 and via 406 connecting pieces of wiring in different layers.

Hybrid mold 200 includes at least body 201 made of an optically transparent material, pillar structure 202, and masking pattern 203.

Masking pattern 203 is made of an opaque material, and is provided on first surface 201A of body 201. Pillar structure 202 includes a plurality of pillars 202A that protrudes from second surface 201B of body 201, second surface 201B being opposite to first surface 201A, and that is made of an optically transparent material.

Masking pattern 203 has shape and placement as viewed from a direction orthogonal to first surface 201A, the shape and placement corresponding to shape and placement of wiring 407 in wiring structure 400. Pillars 202A in pillar structure 202 have shape and placement as viewed from the direction orthogonal to first surface 201A, the shape and placement corresponding to shape and placement of vias 406 in wiring structure 400.

Hybrid mold 200 configured as described above can form multistage recesses in an insulating structure in wiring structure 400 without providing multistage steps. Then, only pillar structure 202 including the plurality of pillars 202A equal in height is buried in the insulating structure, thus improving mold releasability when hybrid mold 200 is released from the insulating structure. Additionally, hybrid mold 200 can be formed by aligning masking pattern 203 with pillar structure 202, thus enhancing alignment accuracy between wiring 407 formed in wiring structure 400 and vias 406, and reducing defects in shape and electrical characteristics of wiring structure 400. Consequently, a manufacturing yield of wiring structure 400 can be reduced to reduce manufacturing cost.

The optically transparent material constituting body 201 and pillar structure 202 in hybrid mold 200 is preferably quartz glass. A material of masking pattern 203 is preferably chromium.

Hybrid mold 200 configured as described above can secure solidity and thermal stability of body 201 and pillar structure 202. Masking pattern 203 made of chromium can exhibit high light shielding properties against UV light.

Second hard mask layer 306 may contain another substance containing inevitable impurities in a range without significantly inhibiting light shielding properties and affecting a yield of wiring structure 400. Thus, second hard mask pattern 309 obtained by processing second hard mask layer 306, that is, masking pattern 203 may contain the other substance containing the inevitable impurities. That is, masking pattern 203 is preferably and mainly made of chromium.

Pillar 202A has a length in the direction orthogonal to first surface 201A, the length being preferably the sum of a thickness of wiring 407 in wiring structure 400 and a length of second via 406B connected to wiring 407 in its thickness direction. The length of pillar 202A in the direction orthogonal to first surface 201A is preferably equal to a length of first via 406A in wiring structure 400.

Consequently, a length of via 406 can be easily adjusted to a design value in wiring structure 400.

A method for manufacturing hybrid mold 200 according to the present exemplary embodiment includes at least a plurality of steps described below.

First hard mask layer 302 is formed on the back surface of base 301 made of an optically transparent material.

First resist film 303 is formed on first hard mask layer 302, and first resist film 303 is processed to form first resist pattern 304.

First hard mask layer 302 is etched using first resist pattern 304 as a mask to form first hard mask pattern 305.

Base 301 is etched using first hard mask pattern 305 as a mask to form pillar structure 202 including the plurality of pillars 202A. First resist pattern 304 may be removed before base 301 is etched, or may be removed after base 301 is etched. First hard mask pattern 305 is removed after base 301 is etched in the present exemplary embodiment.

Then, masking pattern 203 made of an opaque material is formed on the surface of base 301.

The present exemplary embodiment enables obtaining hybrid mold 200 capable of forming recesses corresponding to multistage steps in wiring structure 400 by a simple manufacturing process without providing multistage steps.

Masking pattern 203 may be formed by a plurality of steps described below.

Second hard mask layer 306 is formed on the surface of base 301. Second resist film 307 is formed on second hard mask layer 306, and second resist film 307 is processed to form second resist pattern 308. Second hard mask layer 306 is etched using second resist pattern 308 as a mask to form second hard mask pattern 309. Then, second resist pattern 308 is removed. In these steps, second hard mask pattern 309 serves as masking pattern 203.

Masking pattern 203 formed as described above enables the same equipment and method as those for forming first hard mask pattern 305 to be used, and thus suppressing increase in manufacturing cost of hybrid mold 200.

Alternatively, masking pattern 203 may be also formed by a plurality of steps described below.

A resist pattern having an opening pattern is formed on the surface of base 301. The opening pattern is used to form a reflective material on the surface of base 301. Specifically, the reflective material is applied to the surface of base 301, including the resist pattern. The reflective material is fixed to the surface of base 301 as masking pattern 203. Then, the resist pattern is removed.

The opening pattern has shape and placement as viewed from the direction orthogonal to the surface of base 301, the shape and placement corresponding to the shape and placement of masking pattern 203.

When first hard mask layer 302 or second hard mask layer 306 is formed, the method described above, that is, the vapor deposition method, is typically used. However, vapor deposition equipment includes an evacuation facility, and thus has a high equipment price. In contrast, a coating apparatus for applying the reflective material is less expensive than general vapor deposition equipment. That is, manufacturing cost of manufacturing masking pattern 203 can be reduced.

Although second hard mask layer 306 is formed after first hard mask layer 302 is formed in the present exemplary embodiment, a step of forming second hard mask layer 306 may be performed before first hard mask layer 302 is formed or performed simultaneously when first hard mask layer 302 is formed.

As illustrated in FIG. 3A, after first hard mask layer 302 and second hard mask layer 306 are formed, first resist film 303 may be formed on first hard mask layer 302.

Wiring structure 400 according to the present exemplary embodiment includes first base 401, an insulating structure in which a first insulating layer and a second insulating layer are stacked, and wiring 407 and vias 406 provided in the insulating structure.

The second insulating layer is provided on the surface of first base 401. The first insulating layer is provided on a surface of the second insulating layer. Wiring 407 has a side surface in contact with the first insulating layer, and vias 406 are in contact with at least the second insulating layer. Specifically, first via 406A has a side surface in contact with the first insulating layer and the second insulating layer. Second via 406B has a side surface in contact with the second insulating layer.

The first insulating layer is photo-cured product 403A of photoresist 403, and the second insulating layer is thermally-cured product 402A of non-photoresist 402.

Wiring structure 400 configured as described above enables wiring 407 and vias 406 to be collectively formed, so that a manufacturing yield of wiring structure 400 can be improved, and defects in shape and electrical characteristics of wiring structure 400 can be reduced.

The method for manufacturing wiring structure 400 according to the present exemplary embodiment is performed using hybrid mold 200, and includes at least a plurality of steps described below.

After non-photoresist 402 is applied to the surface of first base 401, heating is performed at a first temperature. Photoresist 403 is applied to the surface of non-photoresist 402 having been heated. First base 401 is heated at a second temperature after being coated with photoresist 403 to reduce fluidity of non-photoresist 402 and photoresist 403. Hybrid mold 200 is pressurized toward first base 401 while viscosity of non-photoresist 402 is reduced and the tip of pillar 202A is brought into contact with photoresist 403. UV light is then emitted from first surface 201A of hybrid mold 200 to form an uncured part on photoresist 403. After hybrid mold 200 is released from photo-cured product 403A in which non-photoresist 402 and photoresist 403 are cured, first base 401 is heated at a third temperature to fully cure non-photoresist 402. Subsequently, uncured photoresist 403 is removed by cleaning. Vias 406 and wiring 407 are collectively formed by plating recesses formed in a stacked body of photo-cured product 403A and thermally-cured product 402A. The step of fully curing non-photoresist 402 may be performed after uncured photoresist 403 is removed.

Consequently, vias 406 and wiring 407 can be collectively formed by a simple manufacturing process, so that manufacturing cost of wiring structure 400 can be reduced. Additionally, a recess for forming wiring 407 and a recess for forming via 406 can be formed without changing a position of hybrid mold 200 with respect to first base 401. As a result, alignment accuracy between via 406 and wiring 407 can be enhanced, and defects in shape and electrical characteristics of wiring structure 400 including wiring 407 and via 406 each having a fine dimension on the order of microns can be reduced. Then, a manufacturing yield of wiring structure 400 can be reduced to reduce manufacturing cost.

Hybrid mold 200 is also released while a part of photoresist 403 is not cured, so that an area of the resist in close contact with hybrid mold 200 can be reduced to improve releasability of hybrid mold 200.

Non-photoresist 402 and thermally-cured product 402A thereof, and photoresist 403 and photo-cured product 403A thereof, are each an insulating material. Thus, reliable insulation and separation between a plurality of vias 406, between a plurality of pieces of wiring 407, and between via 406 and wirings 407 separated from each other, can be achieved.

When thickness of photo-cured product 403A is appropriately set, thickness of wiring 407 can be adjusted to a design value. Similarly, when thickness of non-photoresist 402 is appropriately set, length of each of first via 406A and second via 406B can be adjusted to a design value.

### Second exemplary embodiment

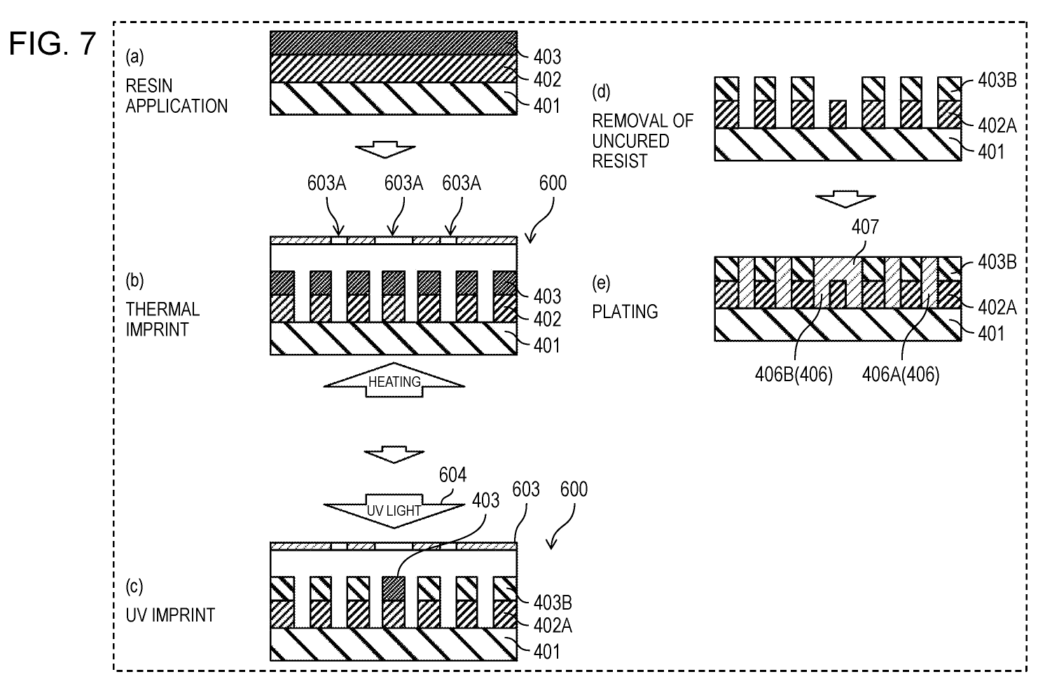

FIG. 6A is a schematic sectional view of a hybrid mold according to a second exemplary embodiment. FIG. 6B is a schematic view of the hybrid mold according to the second exemplary embodiment as viewed from a direction orthogonal to a first surface. FIG. 6C is a perspective view of the hybrid mold according to the second exemplary embodiment. FIG. 7 is a schematic view illustrating a manufacturing step of a wiring structure according to the second exemplary embodiment.

Hybrid mold 600 illustrated in FIGS. 6A to 6C is different from hybrid mold200 illustrated in FIGS. 1A to 1C in shape of masking pattern 603 described below. Masking pattern 603 includes a plurality of opening patterns 603A, and shape and placement of opening pattern 603A viewed from a direction orthogonal to first surface 601A correspond to shape and placement of wiring 407 of wiring structure 400 illustrated in FIG. 5. Hybrid mold 600 is manufactured through procedures illustrated in FIGS. 2A and 2B by a method similar to that for manufacturing hybrid mold 200. Body 601, second surface 601B, pillar structure 602, and pillar 602A in hybrid mold600 correspond to body 201, second surface 201B, pillar structure 202, and pillar 202A in hybrid mold 200, respectively.

Hybrid mold 600 configured as described above can be applied to photoresist 403 that is used for manufacturing wiring structure 400 and that serves as a positive-type insulating resist. The positive-type resist increases in solubility in a developer when being exposed to light. That is, a part irradiated with UV light remains uncured, and an uncured part is removed by cleaning with the developer.

Thus, a method for manufacturing wiring structure 400 illustrated in FIG. 7 is different from the method for manufacturing wiring structure 400 illustrated in FIG. 4 in points below.

In a UV imprint step, when UV light 604 is emitted from above photoresist 403, photoresist 403 located immediately below masking pattern 603 is not irradiated with the UV light. Photoresist 403 in this part is changed to thermally-cured product 403B during full curing processing of non-photoresist 402 to be performed later. Heating temperature at this time is in the same range described above, and is generally about 100°C to 200°C. In contrast, photoresist 403 located immediately below opening pattern 603A remains uncured due to irradiation with the UV light.

Thus, when removal processing of an uncured resist is performed before or after non-photoresist 402 and photoresist 403 are fully cured after hybrid mold 600 is released, photoresist 403 located immediately below masking pattern 603 is removed. Consequently, a recess is formed at a position corresponding to wiring 407 in an insulating structure, and wiring 407 and via 406 can be collectively formed in a plating step to be performed later.

That is, the present exemplary embodiment enables achieving effects similar to those achieved by the configuration and the method described in the first exemplary embodiment. That is, multistage recesses can be formed in the insulating structure in wiring structure 400 without providing multistage steps. Additionally, mold releasability when hybrid mold 600 is released from the insulating structure can be improved. Then, alignment accuracy between wiring 407 formed in wiring structure 400 and via 406 can be enhanced, and defects in shape and electrical characteristics of wiring structure 400 can be reduced. Consequently, a manufacturing yield of wiring structure 400 can be reduced to reduce manufacturing cost.

Hybrid mold 600 capable of forming recesses corresponding to multistage steps in wiring structure 400 can be obtained by a simple manufacturing process without providing multistage steps.

Additionally, via 406 and wiring 407 can be collectively formed by a simple manufacturing process, so that manufacturing cost of wiring structure 400 can be reduced.

### Third exemplary embodiment

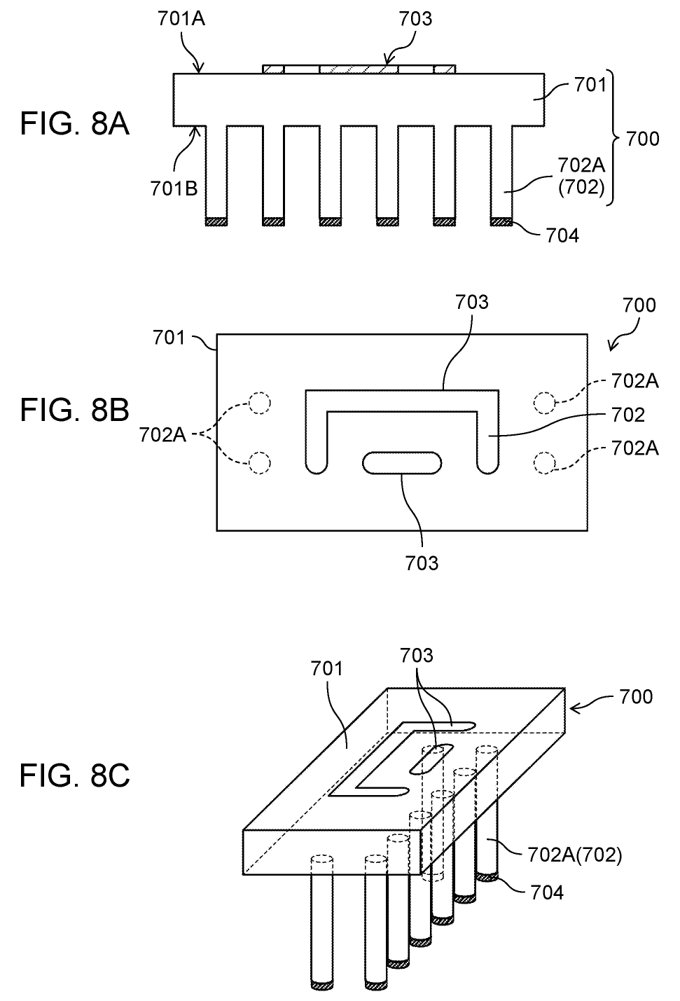

FIG. 8A is a schematic sectional view of a hybrid mold according to a third exemplary embodiment. FIG. 8B is a schematic view of the hybrid mold according to the third exemplary embodiment as viewed from a direction orthogonal to a first surface. FIG. 8C is a perspective view of the hybrid mold according to the third exemplary embodiment.

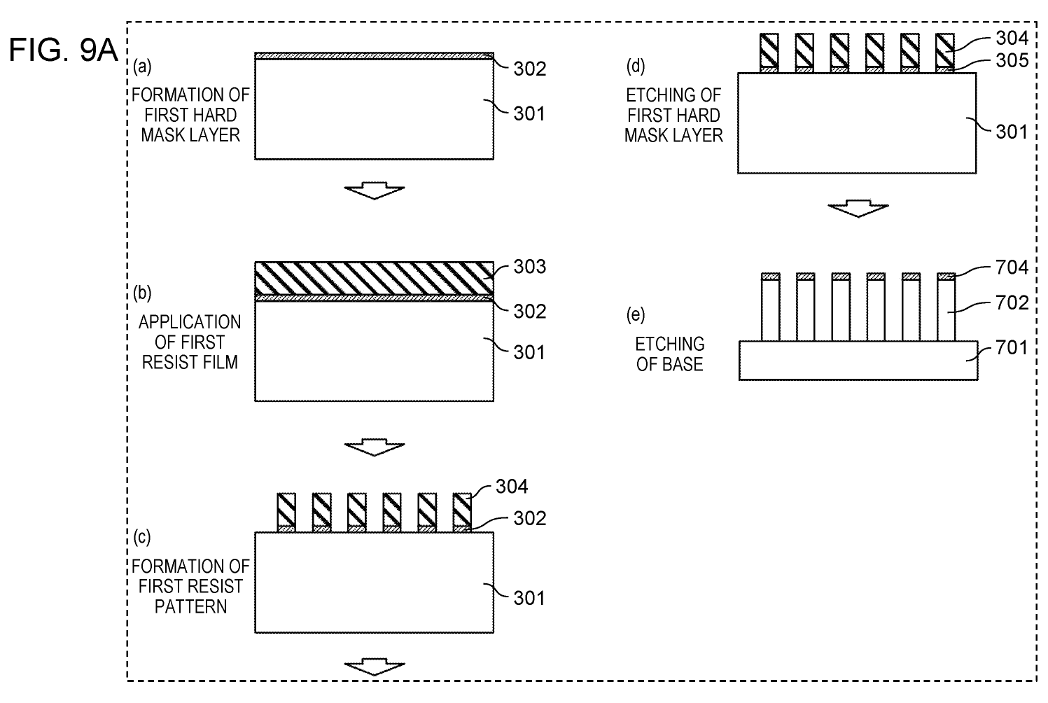

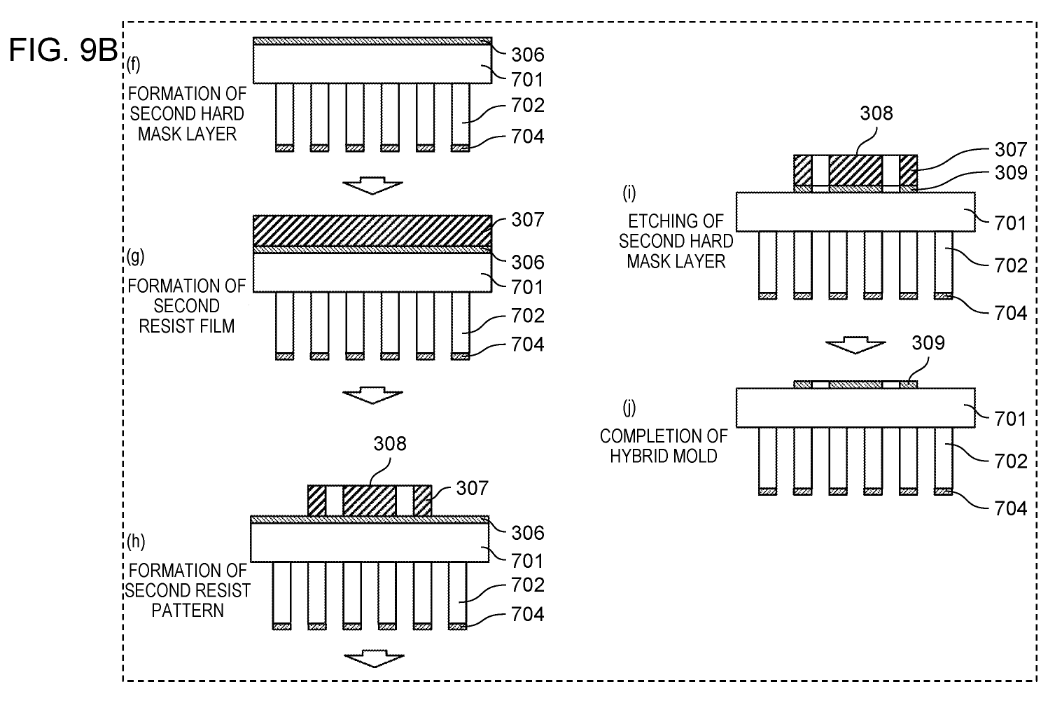

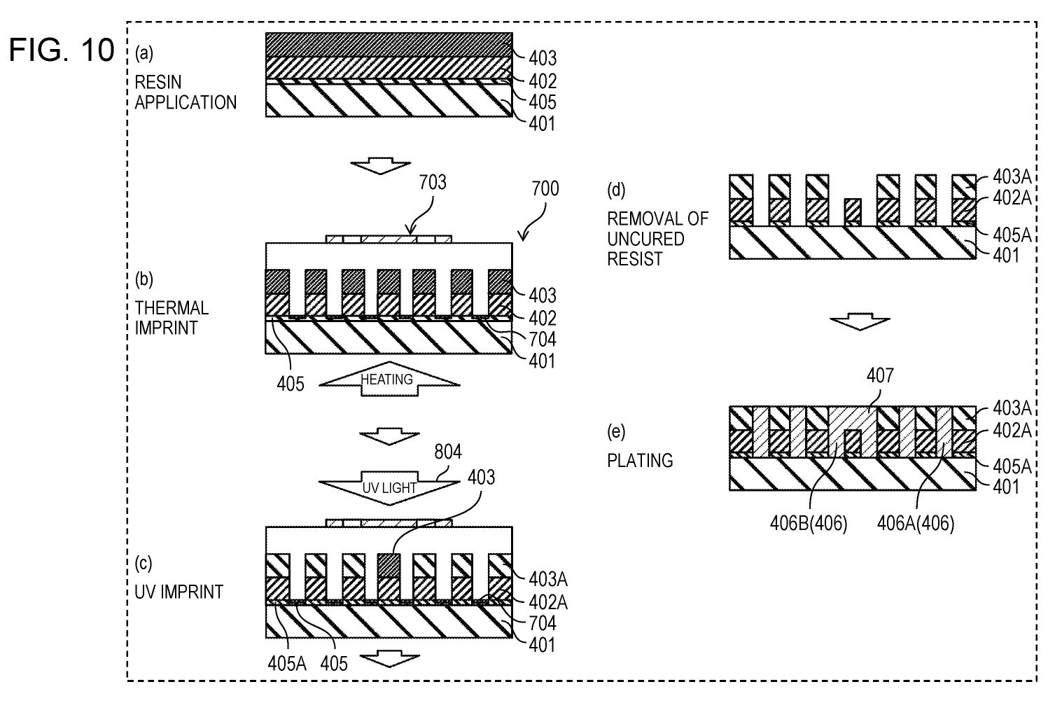

FIG. 9A is a schematic view illustrating a step of manufacturing the hybrid mold according to the third exemplary embodiment. FIG. 9B is a schematic view illustrating a manufacturing step subsequent to that illustrated in FIG. 9A. FIG. 10 is a schematic view illustrating a manufacturing step of a wiring structure according to the third exemplary embodiment.

Hybrid mold 700 illustrated in FIGS. 8A to 8C is different from hybrid mold 200 illustrated in FIGS. 1A to 1C in that first hard mask pattern 704 made of an opaque material is provided at a tip of pillar 702A. Pillar structure 702 includes a plurality of pillars 702A that protrudes from second surface 701B of body 701, second surface 701B being opposite to first surface 701A.

Hybrid mold 700 is manufactured by a method through procedures similar to those for hybrid mold 200. However, after base 301 is etched, subsequent steps are processed while first hard mask pattern 704 is left at the tip of pillar 702A as illustrated in FIGS. 9A and 9B. First hard mask layer 302 in the present exemplary embodiment needs to be made of an opaque material.

FIG. 10 illustrates a method for manufacturing wiring structure 400, the method being different from the method for manufacturing wiring structure 400 illustrated in FIG. 4 in points below.

First, photoresist 405 is applied to a surface of first base 401, and then non-photoresist 402 is applied. Before non-photoresist 402 is applied, photoresist 405 is preferably prebaked to be reduced in fluidity. Depending on a type and viscosity of photoresist 405 and performance of a coating apparatus, photoresist 405 preferably has a film thickness equal to or smaller than a film thickness of each of non-photoresist 402 and photoresist 403.

Providing photoresist 405 on the surface of first base 401 enables alleviating unevenness, undulation, warpage, and the like generated on the surface of first base 401. More specifically, applying photoresist 405 to the surface of first base 401 before applying non-photoresist 402 enables a surface of photoresist 405 to be flat by filling unevenness and the like generated on the surface of first base 401. Consequently, film thickness of non-photoresist 402 and photoresist 403 is stabilized, thus enabling a tip of pillar 702A of hybrid mold 700 to reliably pass through non-photoresist 402. From this viewpoint, photoresist 405 preferably has a film thickness of about 1.3 times a height of the unevenness and the like described above, and has a film thickness of 2 μm or less in a practical range.

In the UV imprint step, when UV light 804 is emitted from above photoresist 403, photoresist 403 located immediately below masking pattern 703 is not irradiated with the UV light and remains uncured, which is similar to that described in the first exemplary embodiment.

In this step, the UV light having passed through body 701 and propagated to pillars 702A is shielded by first hard mask pattern 704. Thus, photoresist 405 located immediately below first hard mask pattern 704 also remains uncured.

That is, photoresists 403, 405 include parts that are respectively not covered with masking pattern 703 and first hard mask pattern 704 when viewed from a direction orthogonal to first surface 701A of hybrid mold 700. Each of the parts is cured by irradiation with the UV light to be changed into corresponding one of photo-cured products 403A, 405A. In contrast, a part covered with masking pattern 703 or first hard mask pattern 704 remains uncured.

Hybrid mold 700 is released, and then uncured resist removal processing is performed before or after non-photoresist 402 is fully cured. This removal processing is performed to remove photoresist 403 located immediately below masking pattern 603 and photoresist 405 located immediately below first hard mask pattern 704. When photoresist 403 is removed, a recess is formed at a position corresponding to wiring 407 in an insulating structure. Thus, wiring 407 and via 406 can be collectively formed in a plating step that is subsequently performed later.

When photoresist 405 located immediately below first hard mask pattern 704 is removed, a remaining film of the resist remaining between the tip of pillar 702A before being released and first base 401, such as a remaining film of non-photoresist 402, can be easily removed. The remaining film of non-photoresist 402 is lifted off and removed simultaneously when photoresist 405 is removed. The remaining film may be reliably removed by wet cleaning, dry etching, or organic cleaning using an organic solution.

That is, the present exemplary embodiment enables achieving effects similar to those achieved by the configuration and the method described in the first exemplary embodiment. That is, multistage recesses can be formed in the insulating structure in wiring structure 400 without providing multistage steps. Additionally, mold releasability when hybrid mold 700 is released from the insulating structure can be improved. Then, alignment accuracy between wiring 407 formed in wiring structure 400 and via 406 can be enhanced, and defects in shape and electrical characteristics of wiring structure 400 can be reduced. Consequently, a manufacturing yield of wiring structure 400 can be reduced to reduce manufacturing cost.

Hybrid mold 700 capable of forming recesses corresponding to multistage steps in wiring structure 400 can be obtained by a simple manufacturing process without providing multistage steps.

Additionally, via 406 and wiring 407 can be collectively formed by a simple manufacturing process, so that manufacturing cost of wiring structure 400 can be reduced.

The present exemplary embodiment also enables the remaining film of the resist remaining between the tip of pillar 702A before being released and first base 401 to be easily and reliably removed. Consequently, an insulator can be prevented from being interposed between first base 401 and via 406, and occurrence of defects in electrical characteristics can be suppressed by providing a good electrical connection between via 406 and wiring connected to via 406. For example, when first base 401 is a substrate having an electrode, such as a through glass vias (TGV) substrate, an electrical connection between the electrode provided on the TGV substrate and via 406 becomes favorable, and defects in electrical characteristics of the TGV substrate including wiring structure 400 can be reduced. Electrical reliability also can be improved.

### Other exemplary embodiments

Even when base 301 is made of a light transmissive resin in the first to third exemplary embodiments, hybrid mold 200 can be formed by a method similar to those illustrated in FIGS. 2A, 2B, 3A, 3B, 9A, and 9B. Alternatively, hybrid mold 200 can also be formed by a method described below.

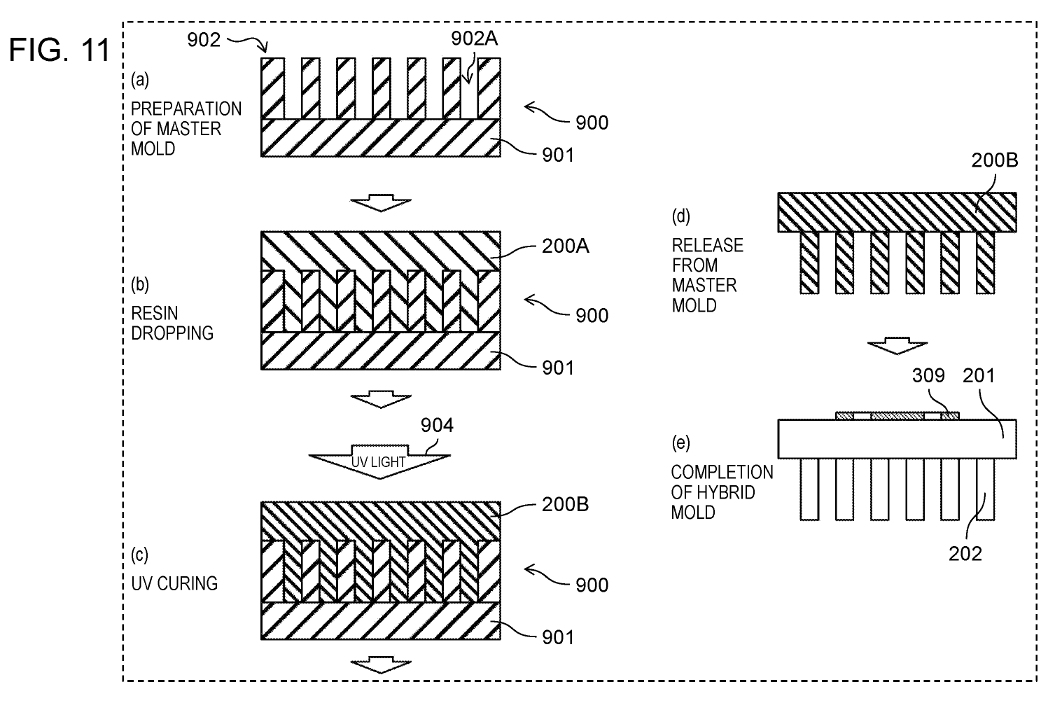

FIG. 11 is a schematic view illustrating a manufacturing step of another hybrid mold.

First, master mold 900 for resin molding is prepared (a: master mold preparation). Master mold 900 is a component in which hole pattern part 902 is provided on a surface of substrate 901. Hole pattern part 902 is a mold frame in which a plurality of through-holes 902A is provided with predetermined placement. The plurality of through-holes 902A has shape and placement, the shape and placement corresponding to shape and placement of vias 406 in wiring structure 400 when viewed in an extending direction of through-holes 902A.

Next, light transmissive resin 200A is dropped onto hole pattern part 902 of master mold 900 (b: resin dropping), and then light transmissive resin 200A is cured to form replica mold 200B of hybrid mold 200. FIG. 11 illustrates an example in which light transmissive resin 200A is a photocurable material, and thus light transmissive resin 200A is cured by irradiation with UV light 904 (c: UV curing). However, light transmissive resin 200A is not particularly limited to the example. When light transmissive resin 200A is a thermosetting material, for example, light transmissive resin 200A including master mold 900 is heated to thermally cure light transmissive resin 200A.

Next, replica mold 200B is released from master mold 900 (d: release from the master mold), and masking pattern 203 is formed on a first surface of replica mold 200B to obtain hybrid mold 200 (e: hybrid mold completion).

Although FIG. 11 does not illustrate details of a method for forming masking pattern 203, masking pattern 203 is formed by a method similar to that shown in the first exemplary embodiment. That is, masking pattern 203 is obtained by forming second hard mask pattern 309 or fixing reflective material to the first surface of replica mold 200B.

Master mold 900 may be configured to include a substrate made of a light transmissive resin, on which hole pattern part 902 is mounted, instead of substrate 901. In this configuration, light transmissive resin 200A is filled up to an upper end of through-hole 902A while being prevented from protruding outside. The substrate described above and light transmissive resin 200A or replica mold 200B are bonded during curing of light transmissive resin 200A or after light transmissive resin 200A is cured and before replica mold 200B is released from master mold 900. A method of the bonding may be thermal bonding or another method.

The components illustrated in the first to third exemplary embodiments including the example illustrated in FIG. 11 can be appropriately combined to form an additional exemplary embodiment. For example, masking pattern 603 illustrated in FIGS. 6A to 6C may be applied to hybrid mold 200 illustrated in FIG. 11.

The present disclosure enables a wiring structure including wiring and vias to be easily manufactured and processed. Mold releasability of a hybrid mold during manufacturing of a wiring structure also can be improved. Additionally, manufacturing cost can be reduced by suppressing a decrease in a yield of the wiring structure.

The hybrid mold of the present disclosure can easily manufacture and process a wiring structure including wiring and vias, and is useful in manufacturing an interposer including a multilayer wiring structure, for example.

What is claimed is:

1. A hybrid mold that is used for forming a wiring structure including wiring and vias connecting pieces of the wiring in different layers to each other, the hybrid mold comprising:
a body made of an optically transparent material;
a masking pattern made of an opaque material and disposed on a first surface of the body; and
a pillar structure including a plurality of pillars made of the optically transparent material and protruding from a second surface of the body, the second surface being opposite to the first surface,
wherein the masking pattern has shape and placement corresponding to shape and placement of the wiring when viewed from a direction orthogonal to the first surface, and
the plurality of pillars each has shape and placement corresponding to shape and placement of the vias when viewed from the direction orthogonal to the first surface.

2. The hybrid mold according to claim 1, wherein
the optically transparent material is quartz glass, and
the masking pattern is mainly made of chromium.

3. The hybrid mold according to claim 1, wherein each of the plurality of pillars has a length in a direction orthogonal to the first surface, the length being a sum of a thickness of the wiring in a second layer in the wiring structure and a length of each of the vias connected to the wiring in the second layer in a thickness direction of the wiring.

4. The hybrid mold according to claim 1, wherein each of the plurality of pillars includes a tip provided with a first hard mask pattern made of an opaque material.

5. A method for manufacturing a hybrid mold used for forming a wiring structure including wiring and vias connecting pieces of the wiring in different layers to each other, the method comprising steps of:
forming a first hard mask layer on a back surface of a base made of an optically transparent material;
forming a first resist film on the first hard mask layer and processing the first resist film to form a first resist pattern;
etching the first hard mask layer using the first resist pattern as a mask to form a first hard mask pattern;
etching the base using the first hard mask pattern as a mask to form a pillar structure including a plurality of pillars; and
forming a masking pattern made of an opaque material on a surface of the base.

6. The method for manufacturing the hybrid mold according to claim 5, wherein
the step of forming a masking pattern includes steps of:
forming a second hard mask layer on the surface of the base;
forming a second resist film on the second hard mask layer and processing the second resist film to form a second resist pattern;
etching the second hard mask layer using the second resist pattern as a mask to form a second hard mask pattern; and
removing the second resist pattern, and
the second hard mask pattern is the masking pattern.

7. The method for manufacturing the hybrid mold according to claim 5, wherein
the step of forming a masking pattern includes steps of:
forming a resist pattern including an opening pattern on the surface of the base;
forming a reflective material on the surface of the base using at least the opening pattern; and
fixing the reflective material to the surface of the base as the masking pattern, and
the opening pattern has shape and placement corresponding to shape and placement of the masking pattern when viewed from a direction orthogonal to the surface of the base.

8. The method for manufacturing the hybrid mold according to claim 5, wherein
the first hard mask layer is made of the opaque material, and
the first hard mask pattern is left at a tip of each of the plurality of pillars.

9. A wiring structure comprising:
a first base;
an insulating structure in which a first insulating layer and a second insulating layer are stacked; and
wiring and via disposed in the insulating structure,
wherein the second insulating layer is disposed on a surface of the first base,
the first insulating layer is disposed on a surface of the second insulating layer,
the wiring has a side surface in contact with the first insulating layer,
the via has a side surface in contact with at least the second insulating layer,
the first insulating layer is a cured product of a photosensitive material, and
the second insulating layer is a cured product of a non-photosensitive material.

10. A method for manufacturing a wiring structure using the hybrid mold according to claim 1, the method comprising steps of:
applying a non-photoresist to a surface of a first base and then heating the non-photoresist at a first temperature;
applying a photoresist to a surface of the non-photoresist after the heating;
heating the first base at a second temperature to reduce fluidity of the non-photoresist and the photoresist after the photoresist is applied;
pressurizing the hybrid mold toward the first base while the fluidity of the non-photoresist is reduced and a tip of each of the plurality of pillars is in contact with the photoresist;
forming an uncured part in the photoresist by emitting UV light from the first surface of the hybrid mold;
releasing the hybrid mold from the non-photoresist and the photoresist;
removing the photoresist uncured by cleaning;
heating the first base at a third temperature after performing the step of releasing the hybrid mold or after performing the step of removing the photoresist uncured to fully cure at least the non-photoresist; and
plating a recess formed in a stacked body of a cured product of the photoresist and a cured product of the non-photoresist to collectively form the vias and the wiring.

11. The method for manufacturing the wiring structure according to claim 10, wherein the non-photoresist and the photoresist are each made of an insulating material.

12. The method for manufacturing the wiring structure according to claim 10, further comprising a step of:
applying the photoresist to the surface of the first base before applying the non-photoresist,
wherein the tip of each of the plurality of pillars is provided with a first hard mask pattern made of an opaque material,
the photoresist provided between the first base and the non-photoresist includes first and second parts when viewed from a direction orthogonal to the first surface, the first part is not covered with the masking pattern and the first hard mask pattern, and is cured by irradiation with the UV light, and the second part is covered with the masking pattern and the first hard mask pattern, and is uncured.
